(19) United States
(12) Patent Application Publication
(10) Pub. No.: US 2024/0260173 A1
(43) Pub. Date: Aug. 1, 2024

(54) METHOD FOR PRODUCING WIRING CIRCUIT BOARD ASSEMBLY SHEET

(71) Applicant: NITTO DENKO CORPORATION, Osaka (JP)

(72) Inventors: Yusaku TAMAKI, Osaka (JP); Rihito FUKUSHIMA, Osaka (JP); Teppei NIINO, Osaka (JP)

(73) Assignee: NITTO DENKO CORPORATION, Osaka (JP)

(21) Appl. No.: 18/561,206

(22) PCT Filed: Jan. 21, 2022
(86) PCT No.: PCT/JP2022/002118

§ 371 Date: Nov. 15, 2023

(30) Foreign Application Priority Data
May 17, 2021 (JP) 2021-083154

(51) Int. Cl. H05K 1/02; H05K 3/00

(52) U.S. Cl. CPC H05K 1/0266; H05K 3/0038; H05K 2201/09936

(57) ABSTRACT

A method for producing a wiring circuit board assembly sheet includes a marking step of forming a mark made of a recessed portion in a metal support board, and after the marking step, an insulating layer forming step of forming a base insulating layer on one surface in a thickness direction of the metal support board formed with the mark.

### TECHNICAL FIELD

The present invention relates to a method for producing a wiring circuit board assembly sheet.

### BACKGROUND ART

Conventionally, various marks are added to a wiring circuit board. More specifically, for example, there is a case where an alignment mark is added to the wiring circuit board. The alignment mark is, for example, used as a reference for alignment of a photomask for a light exposure treatment at the time of production of the wiring circuit board.

More specifically, in the production of a flexible circuit board, formation of a through hole as an alignment mark in a metal thin board has been known. That is, in the production of the flexible circuit board, a resist layer is formed at an arbitrary position by light exposure with the through hole as the reference. Then, a Cu layer or the like is formed in an opening portion of the resist layer (ref: for example, Patent Document 1).

Further, for example, there is a case where a trace mark is added to the wiring circuit board. The trace mark is formed to ensure traceability of the wiring circuit board.

More specifically, for example, in the production of the wiring circuit board, it is known that a base insulating layer, a conductive layer, and a cover insulating layer are laminated in order on the upper surface of a metal support layer, and thereafter, a mark made of a recessed portion is formed in a portion of the metal support layer exposed from the base insulating layer and the cover insulating layer (ref: for example, Patent Document 2 (Example 1)).

### CITATION LIST

### Patent Document

Patent Document 1: Japanese Unexamined Patent Publication No. 2006-253253
Patent Document 2: Japanese Unexamined Patent Publication No. 2011-124491

### SUMMARY OF THE INVENTION

### Problem to be Solved by the Invention

However, in the production of the wiring circuit board, in the formation of the insulating layer, there is a case where a varnish of a resin is used. In such a case, as described in Patent Document 1, when the through hole as the alignment mark is formed in the metal thin board, the varnish of the resin overflows from the through hole, causing a decrease in the yield of the wiring circuit board. That is, the alignment mark is added to improve productivity of the wiring circuit board, and when the mark is the through hole, there is a case where the productivity of the wiring circuit board is lowered.

Further, in the production of the wiring circuit board described in Patent Document 2, when the base insulating layer, the conductive layer, and the cover insulating layer are laminated on the upper surface of the metal support layer, and thereafter, the trace mark is formed in the metal support layer, it is possible to ensure the traceability as for the wiring circuit board after the production. However, when the trace mark is added to a product after the production, an intermediate product in the middle of the production cannot be controlled, and the productivity of the wiring circuit board cannot be improved.

The present invention provides a method for producing a wiring circuit board assembly sheet which is capable of improving productivity, while maintaining a function of a mark in the middle of production.

### Means for Solving the Problem

The present invention [1] includes a method for producing a wiring circuit board assembly sheet including a marking step of forming a mark made of a recessed portion in a metal support board, and after the marking step, an insulating layer forming step of forming an insulating layer on one surface in a thickness direction of the metal support board formed with the mark.

In the method for producing a wiring circuit board assembly sheet, the mark is formed in the metal support board in the marking step. Thereafter, the insulating layer is formed on one surface in the thickness direction of the metal support board. That is, in the method for producing a wiring circuit board assembly sheet, the mark is formed before the formation of the insulating layer.

Therefore, in the marking step, when the trace mark is formed as the mark, it is possible to ensure traceability of an intermediate product in the middle of production.

Further, in the marking step, when the alignment mark is formed as the mark, it is possible to efficiently produce the wiring circuit board assembly sheet.

On the other hand, in a case where the mark is formed before the formation of the insulating layer, when the mark is a through hole, a varnish for forming the insulating layer may overflow from the through hole. However, in the method for producing a wiring circuit board assembly sheet, the mark is made of a recessed portion. Therefore, it is possible to suppress overflow of the varnish, and to improve the yield of the wiring circuit board assembly sheet.

As a result, according to the method for producing a wiring circuit board assembly sheet, it is possible to improve productivity of the wiring circuit board assembly sheet, while maintaining a function of the mark in the middle of the production.

The present invention [2] includes the method for producing a wiring circuit board assembly sheet described in the above-described [1], wherein the mark includes a trace mark.

In the method for producing a wiring circuit board assembly sheet, since the trace mark is formed in the marking step, it is possible to ensure the traceability in the middle of the production of the wiring circuit board assembly sheet.

The present invention [3] includes the method for producing a wiring circuit board assembly sheet described in the above-described [1] or [2], wherein the mark includes an alignment mark.

In the method for producing a wiring circuit board assembly sheet, since the alignment mark is formed in the marking step, it is possible to efficiently produce the wiring circuit board assembly sheet.

The present invention [4] includes the method for producing a wiring circuit board assembly sheet described in the above-described [1], wherein the mark includes a trace mark and an alignment mark, and in the marking step, the trace mark and the alignment mark are simultaneously formed.

In the method for producing a wiring circuit board assembly sheet, since the trace mark is formed in the marking step, it is possible to ensure the traceability in the middle of the production of the wiring circuit board assembly sheet. Further, since the alignment mark is formed in the marking step, it is possible to improve the yield of the wiring circuit board assembly sheet. Then, since the trace mark and the alignment mark are simultaneously formed, it is possible to further improve the productivity of the wiring circuit board assembly sheet.

The present invention [5] includes the method for producing a wiring circuit board assembly sheet described in the above-described [3] or [4], wherein in the insulating layer forming step, the insulating layer is aligned with the alignment mark as a reference.

In the method for producing a wiring circuit board assembly sheet, since the insulating layer is aligned with the alignment mark formed in the marking step as the reference, the productivity of the wiring circuit board assembly sheet is excellent.

The present invention [6] includes the method for producing a wiring circuit board assembly sheet described in any one of the above-described [1] to [5], wherein the recessed portion is formed by a laser.

In the method for producing a wiring circuit board assembly sheet, since the recessed portion is formed by the laser, the method for producing a wiring circuit board assembly sheet has the excellent productivity of the wiring circuit board assembly sheet.

The present invention [7] includes the method for producing a wiring circuit board assembly sheet described in any one of the above-described [1] to [6], wherein before the marking step, a region where the mark is formed and its periphery are subjected to a surface smoothing treatment.

In the method for producing a wiring circuit board assembly sheet, since the region where the mark is formed and its periphery are subjected to the surface smoothing treatment, it is possible to improve recognition of the mark.

### Effect of the Invention

According to the method for producing a wiring circuit board assembly sheet of the present invention, it is possible to improve productivity of a wiring circuit board assembly sheet, while maintaining a function of a mark in the middle of production of the wiring circuit board assembly sheet.

### BRIEF DESCRIPTION OF THE DRAWINGS

FIG. 1 shows a plan view of one embodiment of a wiring circuit board assembly sheet.

FIG. 2 shows an A-A cross-sectional view of the wiring circuit board assembly sheet shown in FIG. 1.

FIGS. 3A to 3C show process views for illustrating a method for producing the wiring circuit board assembly sheet shown in FIG. 1:

FIG. 3A illustrating a step of preparing a metal support board,

FIG. 3B illustrating a step of subjecting a mark forming region of the metal support board to a surface smoothing treatment, and

FIG. 3C illustrating a step of forming a mark in the mark forming region of the metal support board.

FIGS. 4A to 4C, subsequent to FIG. 3, show process views for illustrating the method for producing the wiring circuit board assembly sheet:

FIG. 4A illustrating a step of forming a base insulating layer on the surface of the metal support board,

FIG. 4B illustrating a step of forming a conductive layer on the surface of the base insulating layer, and

FIG. 4C illustrating a step of forming a cover insulating layer on the conductive layer.

### DESCRIPTION OF EMBODIMENTS

### 1. Wiring Circuit Board Assembly Sheet

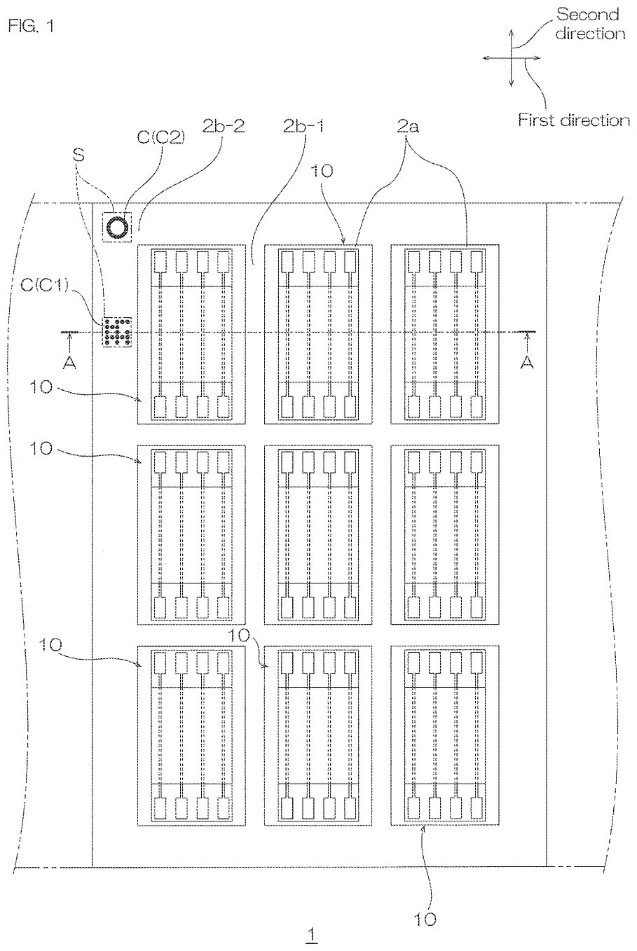

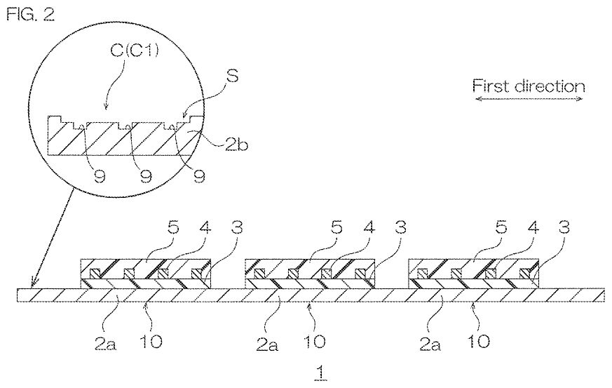

In FIGS. 1 and 2, a wiring circuit board assembly sheet 1 has an elongated sheet shape extending along a longitudinal direction. The wiring circuit board assembly sheet 1 has a predetermined length in a width direction perpendicular to the longitudinal direction. The wiring circuit board assembly sheet 1 has one surface and the other surface opposite to each other at intervals in a thickness direction perpendicular to the longitudinal direction and the width direction.

In the following, the longitudinal direction in which the wiring circuit board assembly sheet 1 extends may be referred to as a first direction. Further, the width direction perpendicular to the longitudinal direction in a plane direction of the wiring circuit board assembly sheet 1 may be referred to as a second direction. Further, one surface in the thickness direction may be referred to as a surface. Further, the other surface in the thickness direction may be referred to as a back surface.

The wiring circuit board assembly sheet 1 includes a metal support board 2. The metal support board 2 has the same shape as the wiring circuit board assembly sheet 1 when viewed from the top. Then, the wiring circuit board assembly sheet 1 includes a plurality of wiring circuit boards 10.

The metal support board 2 is defined by a plurality of circuit forming regions 2a in which the plurality of wiring circuit boards 10 are formed, and a margin region 2b other than the circuit forming region 2a.

In FIG. 1, the plurality of circuit forming regions 2a are defined (nine in FIG. 1), and are disposed at predetermined intervals to each other in the first direction and the second direction. An opening which is not shown is formed around each of the circuit forming regions 2a. The circuit forming regions 2a are connected to the margin region 2b by joints which are not shown. Each of the circuit forming regions 2a has a rectangular shape when viewed from the top.

The margin region 2b is defined between the circuit forming regions 2a adjacent to each other, and in the outer periphery (peripheral end edge of the wiring circuit board assembly sheet 1) of the plurality of circuit forming regions 2a. In the margin region 2b, as the details are described later, a mark C is formed.

In the following, the margin region 2b defined between the circuit forming regions 2a adjacent to each other is referred to as an inner margin region 2b-1. Further, the margin region 2b defined in the outer periphery of the plurality of circuit forming regions 2a is referred to as an outer margin region 2b-2.

Examples of a material for the metal support board 2 include metals. Examples of the metal include copper, copper alloys, and stainless alloys, and preferably, copper and copper alloys are used.

A dimension of the metal support board 2 is appropriately set in accordance with its application and purpose. A thickness of the metal support board 2 is, for example, 10 μm or more, preferably 20 μm or more. Further, the thickness of the metal support board 2 is, for example, 500 μm or less, preferably 250 μm or less.

### 2. Wiring Circuit Board

Each of the plurality of wiring circuit boards 10 is disposed in each of the plurality of circuit forming regions 2a. Thus, the plurality of wiring circuit boards 10 are disposed at predetermined intervals to each other in the first direction and the second direction.

The wiring circuit board 10 includes the metal support board 2 of the circuit forming region 2a, a base insulating layer 3 as one example of an insulating layer, a conductive layer 4, and a cover insulating layer 5.

The metal support board 2 of the circuit forming region 2a supports the base insulating layer 3, the conductive layer 4, and the cover insulating layer 5.

The base insulating layer 3 insulates the conductive layer 4 from the circuit forming region 2a. The base insulating layer 3 is disposed on the surface of the circuit forming region 2a. Examples of the material for the base insulating layer 3 include insulating resins. An example of the insulating resin includes polyimide. The thickness of the base insulating layer 3 is, for example, 1 μm or more, preferably 3 μm or more. Further, the thickness of the base insulating layer 3 is, for example, 35 μm or less.

The conductive layer 4 transmits, for example, an electrical signal. More specifically, the plurality of conductive layers 4 are disposed on the surface of the base insulating layer 3. Each of the conductive layers 4 includes terminals disposed on both end edges in the second direction, and a wiring connecting the terminals. The plurality of conductive layers 4 are disposed spaced from each other in the first direction.

Examples of the material for the conductive layer 4 include metals. Examples of the metal include copper, copper alloys, and stainless alloys, and preferably, copper and copper alloys are used.

The thickness of the conductive layer 4 is, for example, 1 μm or more, preferably 3 μm or more. The thickness of the conductive layer 4 is, for example, 50 μm or less, preferably 30 μm or less. A length in the first direction of the conductive layer 4 is, for example, 5 μm or more, preferably 8 μm or more. The length in the first direction of the conductive layer 4 is, for example, 100 μm or less, preferably 50 μm or less. An interval between the conductive layers 4 adjacent to each other is appropriately set in accordance with the application of the wiring circuit board 10.

The cover insulating layer 5 protects the surface of the conductive layer 4. The cover insulating layer 5 is disposed on the surface of the base insulating layer 3 so as to cover the conductive layer 4. More specifically, the cover insulating layer 5 is in contact with the surface and the side surfaces of the conductive layer 4. Further, the cover insulating layer 5 is in contact with the surface of the base insulating layer 3 around the conductive layer 4. Examples of the material for the cover insulating layer 5 include the above-described insulating resins. Further, the terminals disposed in both end edges in the second direction of the conductive layer 4 are exposed from the cover insulating layer 5.

The thickness of the cover insulating layer 5 is, for example, 2 μm or more, preferably 3 μm or more. Further, the thickness of the cover insulating layer 5 is, for example, 60 μm or less, preferably 40 μm or less.

### 3. Mark

The wiring circuit board assembly sheet 1 includes the mark C. Specifically, in FIG. 1, the wiring circuit board assembly sheet 1 includes a trace mark (tracking identification mark) C1 and an alignment mark (positioning mark) C2 as the mark C.

The trace mark C1 is used to ensure traceability of a product. As the details are described later, the trace mark C1 consists of a code. The trace mark C1 is disposed in the outer margin region 2b-2 of the metal support board 2.

The alignment mark C2 is, for example, used as a reference for alignment in the formation of the base insulating layer 3, the conductive layer 4, and the cover insulating layer 5. As the details are described later, the alignment mark C2 has a geometric shape. The alignment mark C2 is disposed in the outer margin region 2b-2 of the metal support board 2.

In the following, of the outer margin region 2b-2, a region where the mark C is formed is referred to as a mark forming region S. In FIG. 1, the mark forming region S is defined in the outer margin region 2b-2 of a corner portion of the wiring circuit board assembly sheet 1. The mark forming region S and its periphery are subjected to a surface smoothing treatment (described later) from the viewpoint of improving recognition of the mark C.

The mark C is made of a recessed portion 9 formed in the metal support board 2 of the mark forming region S. The recessed portion 9 is a recess which sinks in the metal support board 2 of the mark forming region S in the thickness direction. In other words, the recessed portion 9 is a non-through hole which is recessed downward from the surface of the metal support board 2 of the mark forming region S. The details of a method for forming the mark C made of the recessed portion 9 are described later.

### 4. Method for Producing Wiring Circuit Board Assembly Sheet

The wiring circuit board assembly sheet 1 is produced by the following method.

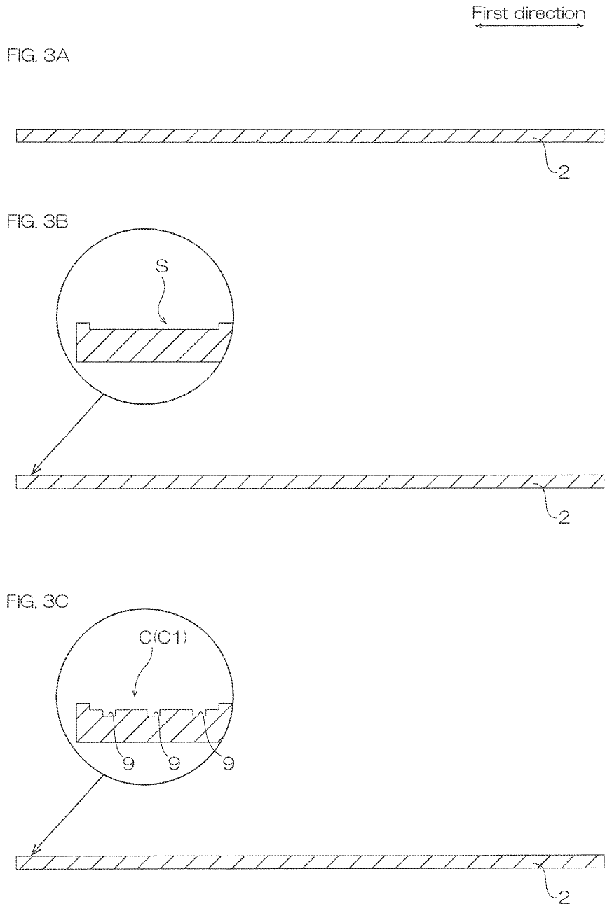

That is, in this method, first, as shown in FIG. 3A, the metal support board 2 is prepared (preparation step). Next, in this method, as shown in FIG. 3B, in the surface of the metal support board 2, before the marking step to be described later, the mark forming region S and its periphery are subjected to the surface smoothing treatment (surface smoothing treatment step).

In the surface smoothing treatment, surface roughness Ra and the maximum height Rz of the mark forming region S and its periphery are adjusted so as to be smaller than the surface roughness Ra and the maximum height Rz of the metal support board 2 which is not subjected to the surface smoothing treatment (the metal support board 2 other than the mark forming region S and its periphery). Thus, it is possible to improve the recognition of the mark C.

Examples of the method for the surface smoothing treatment include a chemical etching method and a laser irradiation method. From the viewpoint of production efficiency of the wiring circuit board 10, preferably, a laser irradiation method is used.

In the laser irradiation method, a laser beam is irradiated from above the metal support board 2 toward the metal support board 2. Examples of the laser beam include solid laser beams, liquid laser beams, and gas laser beams, and preferably, a solid laser beam is used. An example of the laser beam includes the laser beam described in [0041] to [0046] of Japanese Unexamined Patent Publication No. 2011-124491. Thus, it is possible to achieve surface smoothing of the metal support board 2.

Next, in this method, as shown in FIG. 3C, the mark C made of the recessed portion 9 is formed in the metal support board 2 (the mark forming region S) (marking step).

Examples of the method for forming the mark C made of the recessed portion 9 include the chemical etching method and the laser irradiation method. From the viewpoint of the production efficiency of the wiring circuit board 10, preferably, the laser irradiation method is used. That is, the recessed portion 9 is preferably formed by a laser.

In the laser irradiation method, the laser beam is irradiated from above the mark forming region S toward the mark forming region S. Examples of the laser beam include solid laser beams, liquid laser beams, and gas laser beams, and preferably, the solid laser beam is used. An example of the laser beam includes the laser beam described in [0041] to [0046] of Japanese Unexamined Patent Publication No. 2011-124491.

When the laser beam is irradiated, the metal support board 2 sinks in the thickness direction in the mark forming region S. As a result, the recessed portion 9 having an arbitrary shape and size is formed.

More specifically, in the marking step, as the trace mark C1, a code consisting of the recessed portion 9 is formed.

The code allows, for example, arbitrary information to be recorded as digital data. Examples of the information recorded in the code include a production number, a production lot, product detailed information, and manufacturer information. The information recorded in the code is capable of being read based on the number of dots and arrangement by a known method.

Examples of the code include one-dimensional codes and two-dimensional codes. Examples of the one-dimensional code include bar codes and alphanumeric characters. Examples of the two-dimensional code include QR codes (registered trademark), CP codes, 2/4 modulation codes, 3/16 modulation codes, 5/9 modulation codes, and data matrixes. As the code, preferably, a two-dimensional code is used, more preferably, a QR code (registered trademark) and a data matrix are used.

In such a case, the recessed portion 9 forming the trace mark C1 has, for example, a generally circular shape when viewed from the top or a generally square shape when viewed from the top. Preferably, the recessed portion 9 has a generally circular shape when viewed from the top. The size and a depth of the recessed portion 9 when viewed from the top are not particularly limited, and are appropriately set in accordance with its purpose and application.

Then, the plurality of recessed portions 9 form a dot pattern D. The dot pattern D is a pattern in which recessed dots and protruded dots are randomly disposed at an arbitrary number of dots in a two-dimensional region having a generally rectangular shape when viewed from the top. The recessed dot shows a portion where the recessed portion 9 is formed in the two-dimensional region having a generally rectangular shape when viewed from the top. The protruded dot shows a portion where the recessed portion 9 is not formed, and relatively protruding with respect to the recessed portion 9 in the two-dimensional region having the generally rectangular shape when viewed from the top. A ratio of the recessed dot and the protruded dot is not particularly limited, and is appropriately set.

The dot pattern D forms a known two-dimensional code. That is, the plurality of recessed portions 9 form the two-dimensional code having the generally rectangular shape when viewed from the top by the dot pattern D.

Further, in the marking step, a geometric shape made of the recessed portion 9 is formed as the alignment mark C2.

Examples of the geometric shape include ring shapes, circular shapes, elliptical shapes, triangular shapes, quadrangular shapes, hexagonal shapes, and other polygonal shapes. As the geometric shape, preferably, a ring shape is used.

For example, in FIG. 1, the recessed portion 9 forming the alignment mark C2 has a generally ring shape when viewed from the top. The size and the depth of the recessed portion 9 when viewed from the top are not particularly limited, and are appropriately set in accordance with its purpose and application.

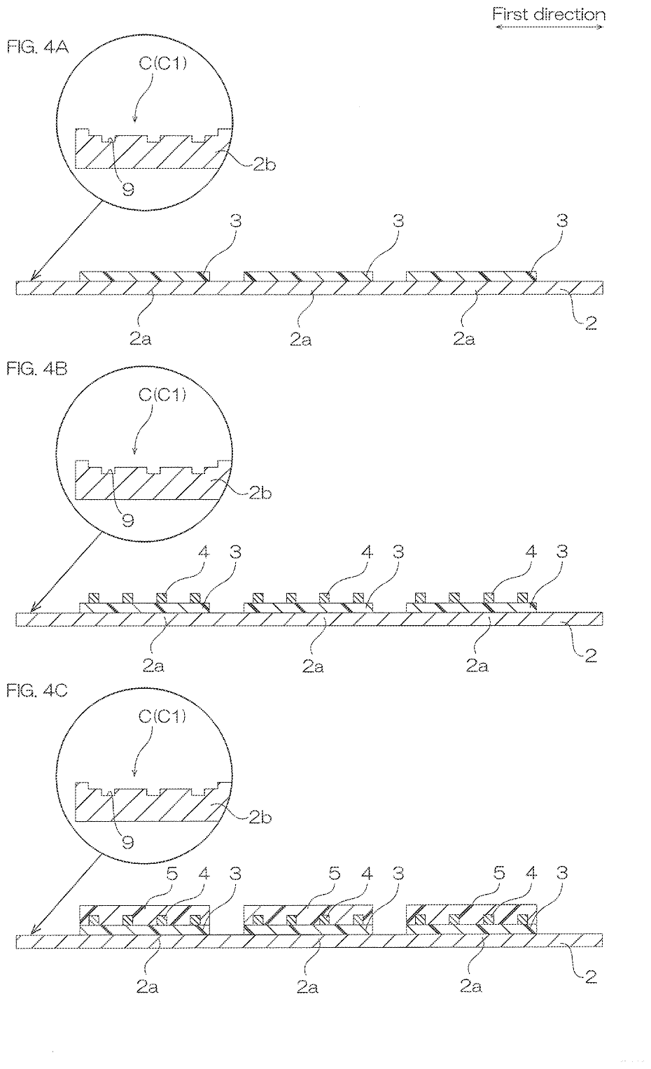

Next, in this method, as referred to FIG. 4A, after the marking step, the base insulating layer 3 is formed on the surface of the metal support board 2 where the mark C is formed (insulating layer forming step (base forming step)).

The method for forming the base insulating layer 3 is not particularly limited, and for example, a varnish containing a polyimide precursor is coated onto the entire upper surface of the metal support board 2 and dried. Thus, a base film is formed on the entire upper surface of the metal support board 2. Next, in this method, a photomask having a pattern corresponding to a desired shape is prepared. Then, the photomask is aligned with the alignment mark C2 as the reference, and the base film is exposed to light through the photomask. Thereafter, the base film is developed, and further, heated and cured. Thus, the base insulating layer 3 containing the polyimide is formed on the metal support board 2.

Next, in this method, as referred to FIG. 4B, after the insulating layer forming step, the conductive layer 4 is formed on the surface of the base insulating layer 3 (conductive layer forming step).

In the conductive layer forming step, the conductive layer 4 is formed on the upper surface of the base insulating layer 3 in an arbitrary circuit pattern. Examples of the method for forming the conductive layer 4 include subtractive methods and additive methods.

In the subtractive method, for example, first, a copper film is formed on the surface of the base insulating layer 3. Next, an etching resist is aligned with the above-described alignment mark C2 as the reference. Thereafter, the copper film is etched through the etching resist. Thus, the conductive layer 4 which is aligned with the alignment mark C2 as the reference is formed.

Further, in the additive method, for example, first, a plating resist is disposed on the surface of the base insulating layer 3. At this time, the plating resist is aligned with the above-described alignment mark C2 as the reference. Next, the conductive layer 4 is formed by a plating method. Thus, the conductive layer 4 which is aligned with the alignment mark C2 as the reference is formed.

Next, in this method, as referred to FIG. 4C, the cover insulating layer 5 is formed on the conductive layer 4 (cover forming step).

The method for forming the cover insulating layer 5 is not particularly limited, and for example, the varnish containing the polyimide precursor is coated onto the entire upper surface of the base insulating layer 3 including the conductive layer 4 and dried. Thus, a cover film is formed on the entire upper surface of the base insulating layer 3 including the conductive layer 4. Next, in this method, the photomask having the pattern corresponding to the desired shape is prepared. Then, the photomask is aligned with the alignment mark C2 as the reference, and the cover film is exposed to light through the photomask. Thereafter, the cover film is developed, and further, heated and cured. Thus, the cover insulating layer 5 containing the polyimide is formed on the upper surface of the base insulating layer 3 containing the conductive layer 4.

Thereafter, if necessary, an opening is formed around each of the wiring circuit boards 10 by etching (not shown).

Thus, the wiring circuit board assembly sheet 1 including the plurality of wiring circuit boards 10 is formed.

### 5. Function and Effect

In the method for producing the wiring circuit board assembly sheet 1 described above, it is possible to control an intermediate product in the middle of production by the trace mark C1 formed in the marking step. Furthermore, in the method for producing the wiring circuit board assembly sheet 1 described above, since the base insulating layer 3, the conductive layer 4, and the cover insulating layer 5 are aligned with the alignment mark C2 formed in the marking step as the reference, the wiring circuit board assembly sheet 1 has excellent productivity.

That is, in the above-described method, the mark C is formed in the margin region 2b of the metal support board 2 in the marking step. Thereafter, the base insulating layer 3 is formed on one surface in the thickness direction of the circuit forming region 2a. That is, in the above-described method, the mark C is formed before the formation of the base insulating layer 3.

Then, in the marking step, the trace mark C1 is formed as the mark C. Therefore, it is possible to ensure the traceability of the intermediate product in the middle of the production.

Further, in the marking step, the alignment mark C2 is formed as the mark C. Therefore, it is possible to efficiently produce the wiring circuit board assembly sheet 1.

On the other hand, in a case where the mark C is formed before the formation of the base insulating layer 3, when the mark C is a through hole, a varnish for forming the base insulating layer 3 may overflow from the through hole. However, in the above-described method, the mark C is made of the recessed portion 9. Therefore, it is possible to suppress the overflow of the varnish, and to improve the yield of the wiring circuit board assembly sheet 1.

As described above, according to the method for producing the wiring circuit board assembly sheet 1 described above, it is possible to improve the productivity of the wiring circuit board assembly sheet 1, while maintaining a function of the mark C in the middle of the production of the wiring circuit board assembly sheet 1.

Further, in the above-described method, since the trace mark C1 and the alignment mark C2 are simultaneously formed, it is possible to further improve the productivity of the wiring circuit board assembly sheet 1.

Further, in the above-described method, since the recessed portion 9 is formed by the laser, the above-described method has the excellent productivity of the wiring circuit board assembly sheet 1.

Further, in the above-described method, since the mark forming region S is subjected to the surface smoothing treatment, it is possible to improve the recognition of the mark C.

### 6. MODIFIED EXAMPLES

In the above-described description, though the mark forming region S and its periphery are subjected to the surface smoothing treatment, it is also possible to omit the surface smoothing treatment.

Further, in the above-described description, the alignment mark C2 is used for the alignment of any of the base insulating layer 3, the conductive layer 4, and the cover insulating layer 5. Alternatively, for example, it is also possible to use the alignment mark C2 only for the alignment of any one of the base insulating layer 3, the conductive layer 4, and the cover insulating layer 5. For example, it is possible to use the alignment mark C2 only for the alignment of the base insulating layer 3.

In this case, for example, a second alignment mark (not shown) used for the alignment of the conductive layer 4 is formed with the alignment mark C2 (first alignment mark) used for the alignment of the base insulating layer 3 as the reference, and it is possible to align the conductive layer 4 with the second alignment mark (not shown) as the reference.

Further, it is possible to form a third alignment mark (not shown) used for the alignment of the cover insulating layer 5 with the first alignment mark C2 used for the alignment of the base insulating layer 3 as the reference, or the second alignment mark (not shown) used for the alignment of the conductive layer 4 as the reference, and it is possible to align the cover insulating layer 5 with the third alignment mark (not shown) as the reference.

Further, though not shown, the mark C may not include the alignment mark C2 as long as it includes the trace mark C1. When the mark C includes at least the trace mark C1, it is possible to ensure the traceability of the wiring circuit board assembly sheet 1.

Further, though not shown, the mark C may not include the trace mark C1 as long as it includes the alignment mark C2. When the mark C includes at least the alignment mark C2, since it is possible to easily align the base insulating layer 3, the conductive layer 4, and the cover insulating layer 5, it is possible to improve the production efficiency of the wiring circuit board assembly sheet 1.

The applications of the wiring circuit board assembly sheet 1 and the wiring circuit board 10 are not particularly limited, and they are used in various fields. The wiring circuit board 10 is, for example, a wiring circuit board for an electronic device (wiring circuit board for an electronic component) and a wiring circuit board for an electrical device (wiring circuit board for an electrical component).

Examples of the wiring circuit board for an electronic device and the wiring circuit board for an electrical device include wiring circuit boards for sensors, wiring circuit boards for vehicles, wiring circuit boards for video equipment, wiring circuit boards for communication relay equipment, wiring circuit boards for information processing terminals, wiring circuit boards for medical equipment, wiring circuit boards for electrical devices, and wiring circuit boards for recording electronic devices.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The method for producing a wiring circuit board assembly sheet of the present invention is preferably used in fields of wiring circuit boards for electronic devices and wiring circuit boards for electrical devices.

### DESCRIPTION OF REFERENCE NUMERALS

1 Wiring circuit board assembly sheet
2 Metal support board
3 Base insulating layer
4 Conductive layer
5 Cover insulating layer
9 Recessed portion
10 Wiring circuit board
C Mark
C1 Trace mark
C2 Alignment mark

1. A method for producing a wiring circuit board assembly sheet comprising:
a marking step of forming a mark made of a recessed portion in a metal support board, and
after the marking step, an insulating layer forming step of forming an insulating layer on one surface in a thickness direction of the metal support board formed with the mark.

2. The method for producing a wiring circuit board assembly sheet according to claim 1, wherein the mark includes a trace mark.

3. The method for producing a wiring circuit board assembly sheet according to claim 1, wherein the mark includes an alignment mark.

4. The method for producing a wiring circuit board assembly sheet according to claim 2, wherein the mark includes an alignment mark.

5. The method for producing a wiring circuit board assembly sheet according to claim 1, wherein the mark includes a trace mark and an alignment mark, and
in the marking step, the trace mark and the alignment mark are simultaneously formed.

6. The method for producing a wiring circuit board assembly sheet according to claim 3, wherein
in the insulating layer forming step, the insulating laver is aligned with the alignment mark as a reference.

7. The method for producing a wiring circuit board assembly sheet according to claim 4, wherein
in the insulating layer forming step, the insulating layer is aligned with the alignment mark as a reference.

8. The method for producing a wiring circuit board assembly sheet according to claim 5, wherein
in the insulating layer forming step, the insulating layer is aligned with the alignment mark as a reference.

9. The method for producing a wiring circuit board assembly sheet according to claim 1, wherein the recessed portion is formed by a laser.

10. The method for producing a wiring circuit board assembly sheet according to claim 1, wherein before the marking step,
a region where the mark is formed and its periphery are subjected to a surface smoothing treatment.
